(19) United States
(12) Patent Application Publication
(10) Pub. No.: US 2025/0060430 A1
(43) Pub. Date: Feb. 20, 2025

(54) DIAMOND SENSOR

(71) Applicant: Element Six Technologies Limited, Didcot, Oxfordshire (GB)

(72) Inventors: Andrew Mark EDMONDS, Didcot, Oxfordshire (GB); Matthew Lee MARKHAM, Didcot, Oxfordshire (GB)

(21) Appl. No.: 18/721,327

(22) PCT Filed: Dec. 19, 2022
(86) PCT No.: PCT/EP2022/086754

§ 371 Date: Jun. 18, 2024

(30) Foreign Application Priority Data
Dec. 23, 2021 (GB) 2118887.5

(51) Int. Cl. G01R 33/12; C30B 29/04

(52) U.S. Cl. CPC G01R 33/1284; C30B 29/04

(57) ABSTRACT

A sensor assembly comprising single crystal diamond material, the single crystal diamond material comprising a surface which is configured in use to contact a fluid, the surface comprising a sensing surface region, wherein the single crystal diamond material comprises a plurality of quantum spin defects in proximity to the sensing surface region. The sensor assembly further comprises a first electrode and a second electrode. The electrodes are located such that, in use, they generate an electric field proximate to a surface of the sensing surface region, the electric field being sufficient to generate oxidising species in the fluid for removing contaminant material from the sensing surface region.

### FIELD

The invention relates to the field of sensors, single crystal diamond materials used for sensors and methods of using such sensors.

### BACKGROUND

Point defects in synthetic diamond material, particularly quantum spin defects and/or optically active defects, have been proposed for use in various imaging, sensing, and processing applications including: luminescent tags; magnetometers; spin resonance devices such as nuclear magnetic resonance (NMR) and electron spin resonance (ESR) devices; spin resonance imaging devices for magnetic resonance imaging (MRI); quantum information processing devices such as for quantum communication and computing; magnetic communication devices; and gyroscopes for example.

It has been found that certain defects are particularly useful for sensing and quantum processing applications when in their negative charge state. For example, the negatively charged nitrogen-vacancy defect (NV⁻) in synthetic diamond material has attracted a lot of interest as a useful quantum spin defect because it has several desirable features including:
(i) Its electron spin states can be coherently manipulated with high fidelity and have an extremely long coherence time (which may be quantified and compared using the transverse relaxation time T₂ and/or T₂′);
(ii) Its electronic structure allows the defect to be optically pumped into its electronic ground state allowing such defects to be placed into a specific electronic spin state even at non-cryogenic temperatures. This can negate the requirement for expensive and bulky cryogenic cooling apparatus for certain applications where miniaturization is desired. Furthermore, the defect can function as a source of photons which all have the same spin state; and
(iii) Its electronic structure comprises emissive and non-emissive electron spin states which allows the electron spin state of the defect to be read out through photons. This is convenient for reading out information from synthetic diamond material used in sensing applications such as magnetometry, spin resonance spectroscopy, and imaging. Furthermore, it is a key ingredient towards using NV⁻ defects as qubits for long-distance quantum communications and scalable quantum computation. Such results make the NV⁻ defect a competitive candidate for solid-state quantum information processing (QIP).

The NV⁻ defect in diamond consists of a substitutional nitrogen atom adjacent to a carbon vacancy. Its two unpaired electrons form a spin triplet in the electronic ground state (³A), the degenerate mₛ=±1 sublevels being separated from the mₛ=0 level by 2.87 GHz. The electronic structure of the NV⁻ defect is such that the mₛ=0 sublevel exhibits a high fluorescence rate when optically pumped. In contrast, when the defect is excited in the mₛ=±1 levels, it exhibits a higher probability to cross over to the non-radiative singlet state (¹A) followed by a subsequent relaxation into mₛ=0. As a result, the spin state can be optically read out, the mₛ=0 state being “bright” and the mₛ=±1 states being dark. When an external magnetic field or strain field is applied, the degeneracy of the spin sublevels mₛ=±1 is broken via Zeeman splitting. This causes the resonance lines to split depending on the applied magnetic/strain field magnitude and its direction. This dependency can be used for magnetometry by probing the resonant spin transitions using microwaves (MW) and using optically detected magnetic resonance (ODMR) spectroscopy to measure the magnitude and, optionally, the direction of the applied magnetic field.

NV⁻ defects in synthetic diamond material can be formed in a number of different ways including:
(i) formation during growth of the synthetic diamond material where a nitrogen atom and a vacancy are incorporated into the crystal lattice as a nitrogen-vacancy pair during growth;
(ii) formation after diamond material synthesis from native nitrogen and vacancy defects incorporated during the growth process by post-growth annealing the material at a temperature (around 800° C.) which causes migration of the vacancy defects through the crystal lattice to pair up with native single substitutional nitrogen defects;
(iii) formation after diamond material synthesis from native nitrogen defects incorporated during the growth process by irradiating the synthetic diamond material to introduce vacancy defects and then subsequently annealing the material at a temperature which causes migration of the vacancy defects through the crystal lattice to pair up with native single substitutional nitrogen defects;
(iv) formation after diamond material synthesis by implanting nitrogen defects into the synthetic diamond material after diamond material synthesis and then annealing the material at a temperature which causes migration of the native vacancy defects through the crystal lattice to pair up with implanted single substitutional nitrogen defects; and
(v) formation after diamond material synthesis by irradiating the synthetic diamond material to introduce vacancy defects, implanting nitrogen defects into the synthetic diamond material before or after irradiation, and annealing the material at a temperature which causes migration of the vacancy defects through the crystal lattice to pair up with implanted single substitutional nitrogen defects.

Various different types of diamond material have been disclosed in the prior art for use in various different types of magnetometry applications including WO2010/010352 and WO2010/010344 which disclose low nitrogen content single crystal chemical vapour deposited (CVD) diamond materials for applications such as magnetometry, and WO2010/149775 which discloses irradiated and annealed single crystal CVD diamond materials for applications such as magnetometry.

A problem with using any material in sensing applications is that where the sensing surface is in contact with a fluid, it can become fouled by contaminants that adhere to the sensing surface. This can degrade the performance of the sensing surface, leading to less accurate information from the sensing surface and potentially a reduced lifetime for the sensor.

### SUMMARY

It is desirable to find a way to remove contaminants from the sensing surface in order to maintain performance and extend the usable lifetime of the sensor. This can be a particular problem where diamond sensors use quantum spin defects such as NV⁻ defects to sense magnetic fields in biological applications, where repeated use of the sensor can lead to contamination from previous samples.

According to a first aspect, there is provided a sensor assembly comprising single crystal diamond material, the single crystal diamond material comprising a surface which is configured in use to contact a fluid, the surface comprising a sensing surface region, wherein the single crystal diamond material comprises a plurality of quantum spin defects in proximity to the sensing surface region. The sensor assembly further comprises a first electrode and a second electrode. The electrodes are located such that, in use, they generate an electric field proximate to a surface of the sensing surface region, the electric field being sufficient to generate oxidising species in the fluid for removing contaminant material from the sensing surface region.

Optional examples of the contaminant material include organic material. For example, the organic material may be proteins where the fluid is a biological fluid, or waxes where the fluid is produced oil.

The first electrode is optionally located at a first electrode surface region of the single crystal diamond material. The first electrode optionally comprises any of electrically conducting boron doped diamond, graphite, and a metal material deposited on the surface of the sensor. Boron doped electrodes may be formed by implanting or overgrowing with boron doped diamond material. Graphite may be formed directly by ablating the diamond material, for example using a laser.

The second electrode is optionally located at a second electrode surface region of the single crystal diamond material, and may comprise any of electrically conducting boron doped diamond, graphite, and a metal material deposited on the surface of the sensor.

As an option, the quantum spin defects are selected from any of silicon containing defects, nickel containing defects, chromium containing defects, germanium containing defects, tin containing defects, and nitrogen containing defects such as negatively charged nitrogen-vacancy defects NV⁻.

As an option, the quantum spin defects are present in a concentration of equal to or greater than: 1×10¹³ defects/cm³; 1×10¹⁴ defects/cm³; 1×10¹⁵ defects/cm³; 1×10¹⁶ defects/cm³; 1×10¹⁷ defects/cm³; or 1×10¹⁸ defects/cm³. These are typical values where the quantum spin defects are formed from defects introduced during growth. As a further option, the concentration of quantum spin defects is equal to or less than: 4×10¹⁸ defects/cm³; 2×10¹⁸ defects/cm³; 1×10¹⁸ defects/cm³; 1×10¹⁷ defects/cm³; or 1×10¹⁶ defects/cm³.

As an alternative option, the quantum spin defects are disposed within 1 μm of the surface, and are present in a concentration of between 1×10⁹ and 1×10¹³ defects/cm². These values are more common where the quantum spin defects are formed from defects introduced by implantation.

The quantum spin defects optionally have a Hahn-echo decoherence time T₂ equal to or greater than 0.01 ms, 0.05 ms, 0.1 ms, 0.3 ms, 0.6 ms, 1 ms, 5 ms, or 15 ms.

As an option, the sensor assembly further comprises a plurality of sensing surface regions, wherein the first electrode surface region is located such that, in use, it generates an electric field over a surface of the plurality of sensing surface regions.

As an option, the sensing surface region has a depth below the sensing surface of between 100 nm and 100 μm.

The sensing surface region is optionally disposed on a further layer of single crystal diamond material.

According to a second aspect, these is provided a single crystal diamond comprising a surface which is configured, in use, to contact a fluid, the surface comprising a sensing surface region, wherein the single crystal diamond comprises a plurality of quantum spin defects in proximity to the sensing surface region. The surface further comprises at least one electrode region, the at least one electrode region configured, in use, to generate an electric field proximate to the sensing surface region, the electric field being sufficient to generate oxidising species in the fluid for removing contaminant material from the sensing surface region.

Optional examples of the contaminant material include organic material. For example, the organic material may be proteins where the fluid is a biological fluid, or waxes where the fluid is produced oil.

The electrode region optionally comprises any of electrically conducting boron doped diamond, graphite, and a metal material deposited on the surface of the single crystal diamond.

As an option, the quantum spin defects are selected from any of silicon containing defects, nickel containing defects, chromium containing defects, germanium containing defects, tin containing defects, and nitrogen containing defects such as negatively charged nitrogen-vacancy defects NV⁻.

As an option, the quantum spin defects are present in a concentration of equal to or greater than: 1×10¹³ defects/cm³; 1×10¹⁴ defects/cm³; 1×10¹⁵ defects/cm³; 1×10¹⁶ defects/cm³; 1×10¹⁷ defects/cm³; or 1×10¹⁸ defects/cm³. These are typical values where the quantum spin defects are formed from defects introduced during growth. As a further option, the concentration of quantum spin defects is equal to or less than: 4×10¹⁸ defects/cm³; 2×10¹⁸ defects/cm³; 1×10¹⁸ defects/cm³; 1×10¹⁷ defects/cm³; or 1×10¹⁶ defects/cm³.

As an alternative option, the quantum spin defects are disposed within 1 μm of the surface, and are present in a concentration of between 1×10⁹ and 1×10¹³ defects/cm². These values are more common where the quantum spin defects are formed from defects introduced by implantation.

The single crystal diamond optionally comprises a plurality of sensing surface regions.

As an option, the sensing surface region has a depth below the sensing surface of between 100 nm and 100 μm.

The sensing surface region is optionally disposed on a further layer of single crystal diamond material.

According to a third aspect, there is provided a method of using a sensor assembly, the sensor assembly comprising single crystal diamond material, a first electrode and a second electrode, the single crystal diamond material comprising a sensing surface region comprising a plurality of quantum spin defects. The method comprises allowing a fluid to pass over the sensing surface region of the single crystal diamond material, and generating an electric field between the first electrode and the second electrode and proximate to the sensing surface region, such that the field generates oxidising species in the fluid, the oxidising species for removing contaminant material from the sensing surface region.

As an option, the method further comprising alternating the electric field polarity between the first and second electrodes. This has been found to reduce the rate of deposition of contaminant material.

As an option, the electric field is generated periodically. For example, the field may be generated purely as a cleaning operation when the device is not in use as a sensor.

The method optionally comprises, prior to generating the electric field, determining that the electric field is to be generated. As a further option, the determining step comprises determining that a measurement obtained from the sensing surface region has deviated from a predetermined value by a predetermined amount.

According to a fourth aspect, there is provided a microfluidic cell comprising a microfluidic channel for receiving a fluid sample and a sensor assembly as described above in the first aspect, the sensor assembly being located adjacent to the microfluidic channel.

### BRIEF DESCRIPTION OF DRAWINGS

Non-limiting embodiments will now be described by way of example and with reference to the accompanying drawings in which:

FIG. 1 illustrates schematically in a block diagram a sensor according to a first exemplary embodiment;

FIG. 2 illustrates schematically in a block diagram a single crystal diamond for use in a sensor according to a second exemplary embodiment;

FIG. 3 illustrates schematically in a block diagram a single crystal diamond for use in a sensor according to a third exemplary embodiment;

FIG. 4 illustrates schematically in a block diagram a single crystal diamond for use in a sensor according to a fourth exemplary embodiment;

FIG. 5 illustrates schematically in a block diagram a single crystal diamond for use in a sensor according to a fifth exemplary embodiment;

FIG. 6 illustrates schematically in a block diagram a sensor according to a sixth exemplary embodiment;

FIG. 7 is a flow diagram showing exemplary steps for operating a sensor.

### DETAILED DESCRIPTION

As discussed above, fouling of the sensing surface of a sensor such as a magnetometer based on diamond with NV⁻ centres can be deleterious to the accuracy and the lifetime of the sensor. Mechanical or chemical cleaning requires down-time for the sensor and in some cases it would be simpler to replace the diamond. The inventors have realised that applying an electric field proximate to the sensing surface can generate oxidising free-radicals in the fluid that is being analysed by the sensor. The oxidising free radicals break down build-up of material on the sensing surface, thereby cleaning the sensing surface.

Such a sensor may be used in a microfluidic cell as described, for example, in U.S. Pat. No. 9,249,526. An exemplary microfluidic comprises a microfluidic channel for receiving a fluid sample, with single crystal diamond sensor being located adjacent to the microfluidic channel. The sensor is positioned adjacent to the channel to sense changes in the magnetic and/or electric field within a sample located in the channel. The microfluidic channel typically has at least one dimension equal to or less than 1 mm, more particularly in the range 100 nm to 1 mm, optionally in the range 500 nm to 500 μm. The size of the microfluidic channel may be chosen to be selective of certain species. More than one channel may be provided. The different channels may have different sizes to be selective of different species based on differences in the size of the species.

There are several ways in which such a sensor can be constructed. The following six embodiments give some examples of sensor construction.

Referring to FIG. 1 herein, there is illustrated schematically in a block diagram a sensor 1 according to a first exemplary embodiment. In this embodiment, the sensor 1 comprises a single crystal diamond material 2. The single crystal diamond material 2 has a surface which is configured in use to contact a fluid to be analysed. The surface includes a sensing surface region 3 that includes a plurality of quantum spin defects. Examples of quantum spin defects include silicon containing defects, nickel containing defects, chromium containing defects, germanium containing defects, tin containing defects, nitrogen containing defects and negatively charged nitrogen-vacancy defects NV⁻. There has recently been a lot of study of the NV⁻ defect in diamond in the field of magnetometers.

The diamond material may have a diamond substrate formed of CVD, HPHT, natural or any other form of diamond. Further diamond is then grown onto the substrate using a CVD process to produce a layer of diamond at the surface with a desired concentration of nitrogen in the solid diamond. This forms the sensing surface region 3, which may be formed only in a part of a surface of the diamond. Parameters such as the nitrogen level can be varied in the source gases according to the desired nitrogen concentration in the final product. Optionally, oxygen, CO or CO₂ can also be added to the growth source gases. After growth, the single crystal diamond material is irradiated and annealed to convert some of the nitrogen in the diamond into NV⁻ centres, making them usable as quantum spin defects. An exemplary process is to irradiate the material for six hours under an electron flux of 3×10¹⁴ cm⁻²s⁻¹ and anneal at 400° C. for 4 hours, 800° C. for 16 hours and then 1200° C. for 2 hours.

An alternative way to create NV⁻ centres is to use diamond substantially free of nitrogen, such as that described in WO01/096633 and WO01/096634, and subsequently implant nitrogen into the surface using ion implantation. This is then followed by the irradiation and annealing steps described above to form NV⁻ centres, although the conditions of irradiation and annealing may be different as the nitrogen is formed much closer to the surface. This technique is described, for example, in WO2015/071497.

In addition to the diamond 2 with the sensing surface region 3, the sensor 1 is also provided with a first electrode 4 and a second electrode 5. Any suitable material may be used for the electrodes. These include electrically conducting boron doped diamond, graphite, and a metal or metal alloy material.

In use, a fluid to be analysed is passed over the sensing surface region 3. When it is desired to remove any build-up of material that is fouling the sensor, an electric field is generated between the electrodes 4, 5 to generate oxidising free radicals in the fluid that break down the material that has built up on the sensing surface region 3.

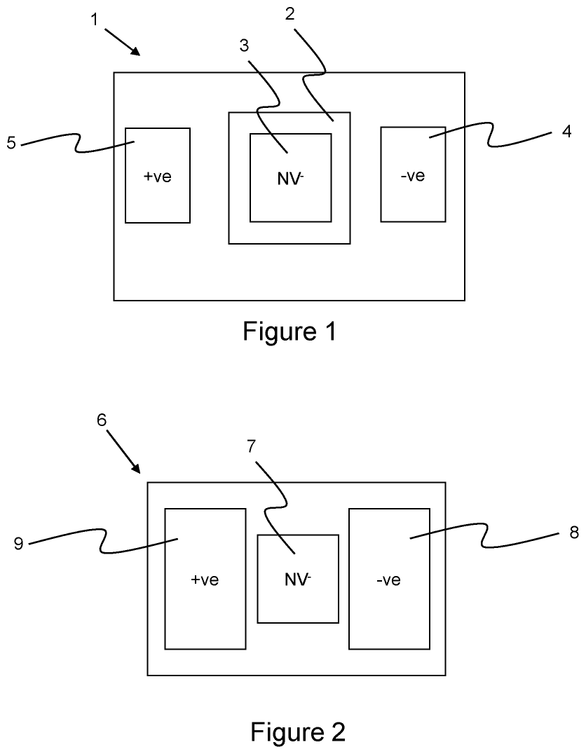

Turning now to FIG. 2, there is illustrated schematically in a block diagram a single crystal diamond for use in a sensor according to a second exemplary embodiment. In this embodiment, the sensor 1 comprises single crystal diamond material. A sensing surface region 7 is formed in a part of a surface of the single crystal diamond material. This can be formed in the same way as described above in the first exemplary embodiment.

The single crystal diamond material also includes a first electrode 8 and a second electrode 9 disposed either side of the sensing surface region. Either of the electrodes 8, 9 may be formed, for example, by boron doping surface regions of the single crystal diamond material, or by graphitising regions of the surface of the single crystal diamond material, or by depositing metal or metal alloys on regions of the single crystal diamond material. The sensor therefore comprises single crystal diamond material that has both a sensing surface region comprising a plurality of quantum spin defects, such as NV⁻ centres, a first electrode surface region forming a first electrode 8 and a second electrode surface region forming a second electrode 9. In this example, the first electrode 8 is a cathode and the second electrode 9 is an anode.

Where the first and second electrode 8, 9 are formed by boron doping diamond, these can be formed by masking the surface of the single crystal diamond material and growing further diamond material using a CVD process in which the source gases include a source of boron.

In use, a fluid to be analysed is passed over the sensing surface region 7. When it is desired to remove any build-up of material that is fouling the sensor, an electric field is generated between the electrodes 8, 9 to generate oxidising free radicals in the fluid that break down the material that has built up on the sensing surface region 7.

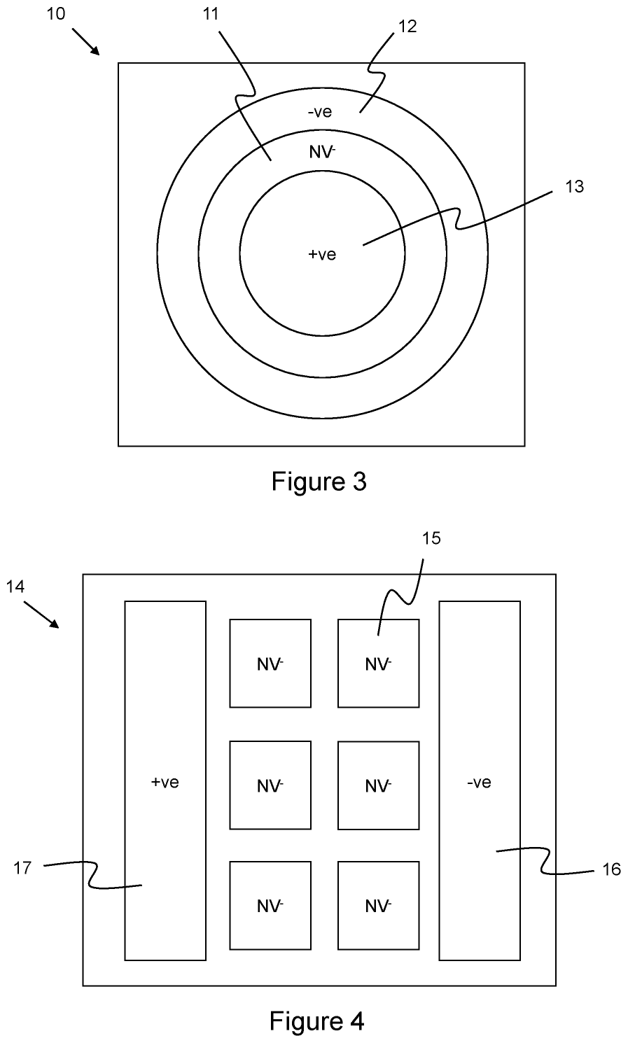

Turning now to FIG. 3, there is illustrated schematically in a block diagram a single crystal diamond for use in a sensor according to a third exemplary embodiment. In this embodiment, the sensor 10 comprises single crystal diamond material. A sensing surface region 11 is formed in an annular shaper in a part of a surface of the single crystal diamond material. This can be formed in the same way as described above in the first exemplary embodiment.

The single crystal diamond material also includes a first electrode 12 and a second electrode 13 disposed either side of the sensing surface region 11. The first electrode 12 is formed in an annular shape at an outer diameter of the sensing surface region 11, and the second electrode 13 is formed either in a circular shape or an annular shape at an inner diameter of the sensing surface region 11. Either of the electrodes 12, 13 may be formed, for example, by boron doping surface regions of the single crystal diamond material, or by graphitising regions of the surface of the single crystal diamond material, or by depositing metal or metal alloys on regions of the single crystal diamond material. The sensor therefore comprises single crystal diamond material that has both a sensing surface region 11 comprising a plurality of quantum spin defects, such as NV⁻ centres, a first electrode surface region forming a first electrode 12 and a second electrode surface region forming a second electrode 13. In this example, the first electrode 12 is a cathode and the second electrode 13 is an anode.

Where the first and second electrode 12, 13 are formed by boron doping diamond, these can be formed by masking the surface of the single crystal diamond material and growing further diamond material using a CVD process in which the source gases include a source of boron.

In use, a fluid to be analysed is passed over the sensing surface region 11. When it is desired to remove any build-up of material that is fouling the sensor, an electric field is generated between the electrodes 12, 13 to generate oxidising free radicals in the fluid that break down the material that has built up on the sensing surface region 11.

Turning now to FIG. 4, there is illustrated schematically in a block diagram a single crystal diamond for use in a sensor 14 according to a fourth exemplary embodiment. In this embodiment, the sensor 14 comprises single crystal diamond material. A plurality of sensing surface regions 15 are formed in a part of a surface of the single crystal diamond material. These can be formed in the same way as described above in the first exemplary embodiment.

The single crystal diamond material also includes a first electrode 16 and a second electrode 17 disposed either side of the plurality of sensing surface regions 15. Either of the electrodes 16, 17 may be formed, for example, by boron doping surface regions of the single crystal diamond material, or by graphitising regions of the surface of the single crystal diamond material, or by depositing metal or metal alloys on regions of the single crystal diamond material. The sensor therefore comprises single crystal diamond material that has both a sensing surface region comprising a plurality of quantum spin defects, such as NV⁻ centres, a first electrode surface region forming a first electrode 8 and a second electrode surface region forming a second electrode 9. In this example, the first electrode 16 is a cathode and the second electrode 17 is an anode.

Where the first and second electrode 16, 17 are formed by boron doping diamond, these can be formed by masking the surface of the single crystal diamond material and growing further diamond material using a CVD process in which the source gases include a source of boron.

In use, a fluid to be analysed is passed over the plurality of sensing surface regions 15. When it is desired to remove any build-up of material that is fouling the sensor, an electric field is generated between the electrodes 16, 17 to generate oxidising free radicals in the fluid that break down the material that has built up on the plurality of sensing surface regions 15. Note also that the sensor 14 can be used for a plurality of different fluids to be tested, with each sensing surface regions of the plurality of sensing surface regions 15 being exposed to a different fluid, and sensing measurements being taken simultaneously.

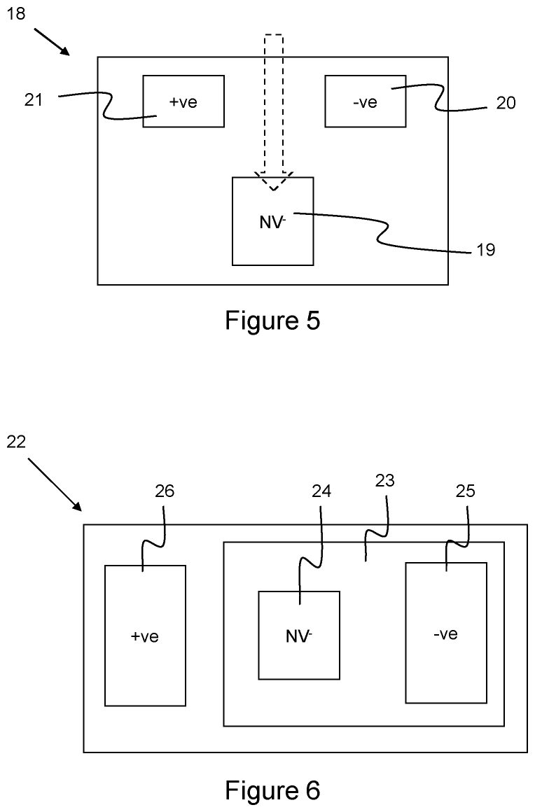

Turning now to FIG. 5, there is illustrated schematically in a block diagram a single crystal diamond for use in a sensor according to a fifth exemplary embodiment. The fifth exemplary embodiment is similar to the second exemplary embodiment, except that the electrodes are located proximate to the sensing surface regions, but not either side of the sending surface region.

The sensor 18 of the fifth exemplary embodiment comprises a sensing surface region 19 is formed in a part of a surface of the single crystal diamond material. This can be formed in the same way as described above in the first exemplary embodiment. The single crystal diamond material also includes a first electrode 20 and a second electrode 21 disposed either side of the sensing surface region, and formed as described in the second exemplary embodiment. However, the electrodes 20, 21 are not located either side of the sensing surface region 19, but still proximate to the sensing surface region 19.

In use, a fluid to be analysed is passed over the sensing surface region 19. When it is desired to remove any build-up of material that is fouling the sensor, an electric field is generated between the electrodes 20, 21 to generate oxidising free radicals in the fluid. If the flow of the fluid is as shown in the arrow of FIG. 5, then the oxidising free radicals pass over the sensing surface region 19 and break down the material that has built up on the sensing surface region 19.

Turning now to FIG. 6, there is illustrated schematically in a block diagram a sensor according to a sixth exemplary embodiment. This embodiment incorporates elements of both the first and second embodiments.

In the sixth exemplary embodiment, the sensor 22 comprises a single crystal diamond material 23. The single crystal diamond material 23 has a surface that is configured in use to contact a fluid to be analysed. The surface includes a sensing surface region 24 that includes a plurality of quantum spin defects, as described above.

The single crystal diamond material 23 also includes a first electrode 25 disposed on the surface as a first electrode region. The first electrode 25 may be formed, for example, by boron doping surface regions of the single crystal diamond material 23, or by graphitising regions of the surface of the single crystal diamond material 23, or by depositing metal or metal alloys on regions of the single crystal diamond material 23. The sensor 22 also comprises a second electrode 26, but this is not disposed on the single crystal diamond material 23.

In use, a fluid to be analysed is passed over the sensing surface region 24. When it is desired to remove any build-up of material that is fouling the sensor, an electric field is generated between the electrodes 25, 26 to generate oxidising free radicals in the fluid that break down the material that has built up on the sensing surface region 24.

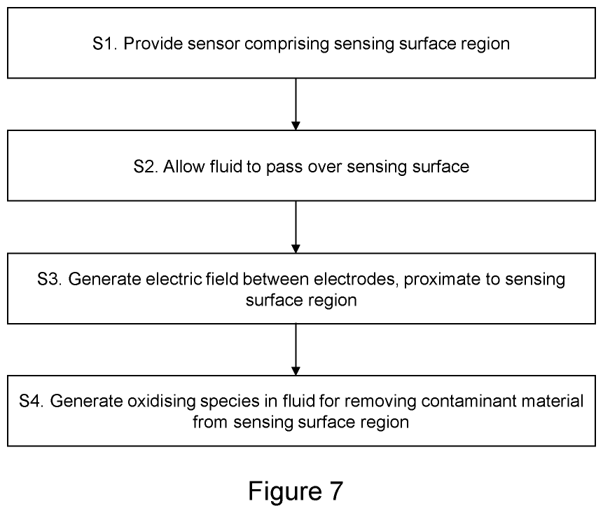

Turning now to FIG. 7, a flow diagram is provided that shows exemplary steps for using a sensor such as those described in the first to sixth exemplary embodiments above. The following numbering corresponds to that of FIG. 7:

S1. A sensor is provided that comprises single crystal diamond material, a first electrode and a second electrode. The single crystal diamond material comprises a sensing surface region comprising a plurality of quantum spin defects. As described above in the first to sixth exemplary embodiments, one or both of the electrodes may be formed integrally and at a surface of the single crystal diamond material, or may be separate from the single crystal diamond material.

S2. A fluid is allowed to pass over the sensing surface region of the single crystal diamond material as the sensor operates.

S3. An electric field is generated between the first electrode and the second electrode. It may be undesirable to generate the electric field constantly, as this could affect the fluid being sensed. The electric field may therefore be generated periodically, after a predetermined time period has elapsed. Alternatively, the electric filed may be generated when a determination is made that the electric field should be generated. For example, a build-up of contaminants such as organic material on the sensing surface region may have a deleterious effect on the performance of the sensing surface region. In this case, a determination may be made that the electric field is to be generated to clean the sensing surface region when a measurement obtained from the sensing surface region has deviated from a predetermined value by a predetermined amount. Note also that the polarity of the electric field may be switched between the electrodes, so that each electrode acts alternately as an anode or a cathode. This

S4. The field generates oxidising species in the fluid, which break down and remove contaminants such as organic material from the sensing surface region. Examples of organic material to be removed include proteins.

Sensors such as those described above may be used to measure several types of fluid. Examples of such fluids include biological fluids, such as blood or urine; produced oil; and other fluids derived from chemical processing. Where biological fluids are used, examples of contaminants include proteins. For produced oil, examples of contaminants can include wax. However, note that contaminants may be non-organic.

By way of example, a sensor according to the third exemplary embodiment was formed as follows:

A single crystal diamond substrate was provided with dimensions of 3×3×0.5 mm and a nitrogen concentration of 1.5 ppb. A mask was placed over a growth surface of substrate and the growth surface was selectively etched using inductively coupled plasma etching. This was performed using Ar and Cl feed gases, although it will be appreciated that oxygen could be used. The etching formed a 10 μm deep annular depression in the growth surface of the substrate. The skilled person will appreciate that other methods could be used to form 10 μm depressions, for example, grinding, machining, chemical-mechanical polishing and so on.

The etched diamond substrate was then placed in a vacuum chamber and a surface cleaning etch was performed using a hydrogen plasma.

The etched diamond substrate was placed in a CVD reactor chamber and further diamond was grown on the substrate to a thickness greater than the depth of the etched depression pattern. The further diamond was grown using the following conditions:
Microwave power=5 kW
Pressure=230 Torr
Hydrogen Flow Rate=600 sccm
Methane Flow Rate=30 sccm
Nitrogen dopant=60 sccm of 1000 ppm N₂ in H₂

The level of nitrogen doping was selected to be relatively high to ensure that the further diamond was grown with a much higher NV⁻ concentration than that of the diamond substrate.

The further diamond was then polished back using mechanical polishing to remove a surface layer of the further diamond, to leave a surface region having a low nitrogen content except in the annular sensor surface region, where the nitrogen concentration was higher.

Parameters such as the nitrogen level can be varied according to the desired nitrogen concentration in the final product. Optionally, oxygen, CO or CO₂ can also be added to the growth process. After growth, the single crystal diamond material was treated using an irradiation and annealing process. This involved irradiating the material for six hours under an electron flux of 3×10¹⁴ cm⁻²s⁻¹ and annealing at 400° C. for 4 hours, 800° C. for 16 hours and then 1200° C. for 2 hours. This process converted nitrogen in the diamond into NV⁻ centres, making them useful as quantum spin defects. 9 and 10, the diamond material of FIGS. 6 and 7 has been further processed.

A mask was placed over the surface of the single crystal diamond material and the surface was selectively etched using inductively coupled plasma etching. This was performed using Ar and Cl feed gases, although it will be appreciated that oxygen could be used. The etching formed a depression pattern in the growth surface of the substrate in the areas where the electrodes were to be formed. The skilled person will appreciate that other methods could be used to form depressions, for example, grinding, machining, chemical-mechanical polishing and so on.

The etched third diamond layer 10 was then cleaned in a hydrogen plasma as described above.

The single crystal diamond material was then placed in a CVD reactor chamber and additional diamond was grown on the substrate to a thickness greater than the depth of the etched depression pattern. The additional diamond was grown using the following conditions:
Microwave power=3.6 kW
Pressure=140 Torr
Hydrogen Flow Rate=600 sccm
Methane Flow Rate=32 sccm
B₂H₆ Flow Rate=19 sccm

The addition of boron was to ensure that the additional diamond had a boron content sufficient to form electrically conductive synthetic diamond, thereby forming the electrodes.

The additional diamond was then polished back using mechanical polishing to remove a surface layer of the additional diamond, to leave the structure shown in FIG. 3 and described in the third exemplary embodiment.

The skilled person will appreciate that where one of the electrodes is formed on the surface of the single crystal diamond material, they can be formed in ways other than boron doping. For example, laser ablation of the surface can cause the single crystal diamond material to graphitise, leaving conductive graphite regions to act as an electrode. Similarly, metals or metals allows can be printed or otherwise deposited on the surface of the single crystal diamond material to form an electrode.

While this invention has been particularly shown and described with reference to preferred embodiments, it will be understood to those skilled in the art that various changes in form and detail may be made without departing from the scope of the invention as defined by the appendant claims. For example, while the examples above used boron doped diamond integrally formed with the sensor, it will be appreciated that one or both electrodes may not be disposed on the single crystal diamond, and need not be formed of boron-doped diamond.

1. A sensor assembly comprising:
single crystal diamond material, the single crystal diamond material comprising a surface which is configured in use to contact a fluid, the surface comprising a sensing surface region, wherein the single crystal diamond material comprises a plurality of quantum spin defects in proximity to the sensing surface region;
a first electrode;
a second electrode
wherein the electrodes are located such that, in use, they generate an electric field proximate to a surface of the sensing surface region, the electric field being sufficient to generate oxidising species in the fluid for removing contaminant material from the sensing surface region.

2. The sensor assembly according to claim 1, wherein the contaminant material comprises organic material.

3. The sensor assembly according to claim 1, wherein the first electrode is located at a first electrode surface region of the single crystal diamond material, and comprises any of:
electrically conducting boron doped diamond;
graphite; and
a metal material deposited on the surface of the sensor.

4. The sensor assembly according to claim 1, wherein the second electrode is located at a second electrode surface region of the single crystal diamond material, and comprises any of:
electrically conducting boron doped diamond;
graphite; and
a metal material deposited on the surface of the sensor.

5. The sensor assembly according to claim 1, wherein the quantum spin defects are selected from any of:
silicon containing defects;
nickel containing defects;
chromium containing defects;
germanium containing defects;
tin containing defects;
nitrogen containing defects; and
negatively charged nitrogen-vacancy defects, NV⁻.

6.-9. (canceled)

10. The sensor assembly according to claim 1, further comprising a plurality of sensing surface regions, wherein the first electrode surface region is located such that, in use, it generates an electric field over a surface of the plurality of sensing surface regions.

11. (canceled)

12. (canceled)

13. A single crystal diamond comprising:
a surface which is configured, in use, to contact a fluid, the surface comprising a sensing surface region, wherein the single crystal diamond comprises a plurality of quantum spin defects in proximity to the sensing surface region;
the surface further comprising at least one electrode region, the at least one electrode region configured, in use, to generate an electric field proximate to the sensing surface region, the electric field being sufficient to generate oxidising species in the fluid for removing contaminant material from the sensing surface region.

14. The single crystal diamond according to claim 13, wherein the electrode region comprises any of:
electrically conducting boron doped diamond;
graphite; and
a metal material deposited on the surface of the single crystal diamond.

15. The single crystal diamond according to claim 13, wherein the quantum spin defects are selected from any of:
silicon containing defects;
nickel containing defects;
chromium containing defects;
germanium containing defects;
tin containing defects;
nitrogen containing defects; and
negatively charged nitrogen-vacancy defects, NV⁻.

16.-18. (canceled)

19. The single crystal diamond according to claim 13, further comprising a plurality of sensing surface regions.

20. (canceled)

21. (canceled)

22. A method of using a sensor assembly, the sensor assembly comprising single crystal diamond material, a first electrode and a second electrode, the single crystal diamond material comprising a sensing surface region comprising a plurality of quantum spin defects, the method comprising:
allowing a fluid to pass over the sensing surface region of the single crystal diamond material; and
generating an electric field between the first electrode and the second electrode and proximate to the sensing surface region, such that the field generates oxidising species in the fluid, the oxidising species for removing contaminant material from the sensing surface region.

23. The method according to claim 22, further comprising alternating the electric field polarity between the first and second electrodes.

24. The method according to claim 22, wherein the electric field is generated periodically.

25. The method according to claim 22, comprising, prior to generating the electric field, determining that the electric field is to be generated.

26. The method according to claim 25, wherein the determining step comprises determining that a measurement obtained from the sensing surface region has deviated from a predetermined value by a predetermined amount.

27. (canceled)
